(19) United States
(12) Patent Application Publication
(10) Pub. No.: US 2010/0128442 A1
(43) Pub. Date: May 27, 2010

(54) HEAT SINK ASSEMBLY

(75) Inventors: ZHI-PING WU, Shenzhen City (CN); XIAO-FENG WANG, Shenzhen City (CN); YU-HSU LIN, San Jose, CA (US); JENG-DA WU, Tu-Cheng (TW); CHIH-HANG CHAO, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTDRY CO., LTD, Tu-Cheng (TW)

(21) Appl. No.: 12/464,519

(22) Filed: May 12, 2009

(30) Foreign Application Priority Data
Nov. 21, 2008 (CN) 200810305684.0

(51) Int. Cl. H05K 7/20

(52) U.S. Cl. 361/710

(57) ABSTRACT

A heat sink assembly includes a printed circuit board, a socket attached on a top surface of the board for receiving a chip, and a heat sink attached onto the chip of the board. The socket includes a plurality of legs integrally extending down from a bottom surface of the socket. The legs contact the top surface of the board to support the socket on the board. The heat sink includes a base, a plurality of fins extending up from the base, and a plurality of legs extending down from the base.

### BACKGROUND

1. Technical Field

The present disclosure relates to a heat sink assembly, and more particularly to a heat sink assembly which effectively protects a computer chip socket.

2. Description of Related Art

With developments in microelectronics technology, electronic devices process data at unprecedented high speeds, producing large amounts of heat. To keep the systems stable and undamaged by the heat, the heat must be efficiently removed. Therefore, heat sinks are frequently used to dissipate heat from these electronic devices.

Conventionally, a heat sink is attached to an electronic device such as a central processing unit (CPU) by a clip. The clip is usually formed from steel. A commonly used heat sink clip assembly includes a clip having a pair of legs spaced apart at their first ends by a contiguous connecting member which is pressed against the heat sink. Because of environmental considerations, solder often used to solder the CPU socket is lead-free, although the lead-free solder is more frangible than that solder including lead. Upon receiving an external force, the lead-free solder on the CPU socket can be easily damaged. Further, the CPU socket under the heat sink receives considerable pressure from the clip pressing the heat sink, which may destabilize the CPU socket.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a first embodiment of a heat sink assembly.

FIG. 2 is a sectional view of the heat sink assembly of FIG. 1.

FIG. 3 is an exploded, isometric view of a second embodiment of a heat sink assembly.

FIG. 4 is a sectional view of the heat sink assembly of FIG. 3.

### DETAILED DESCRIPTION

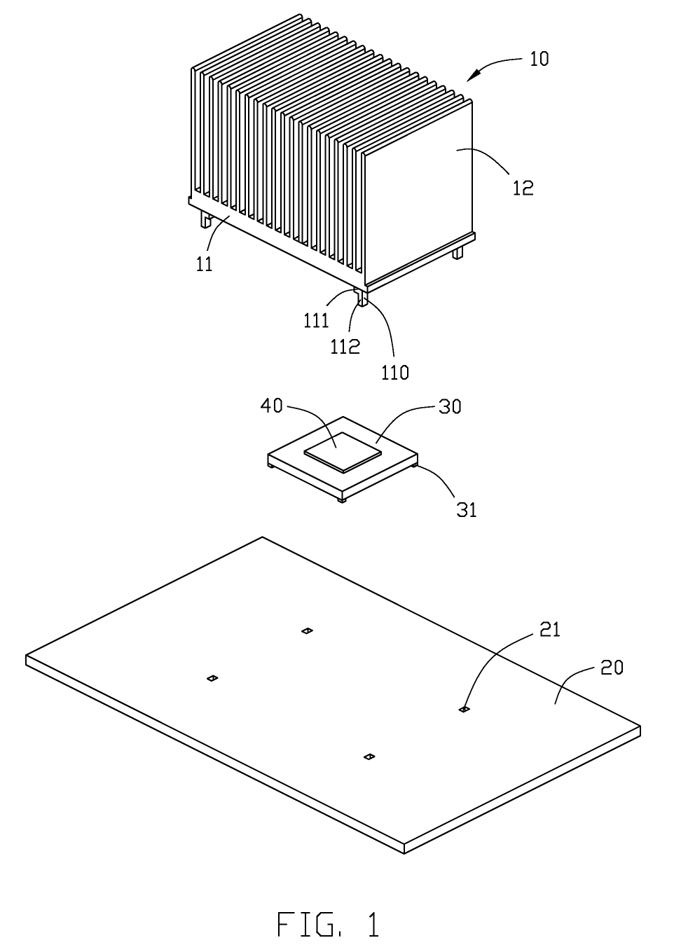

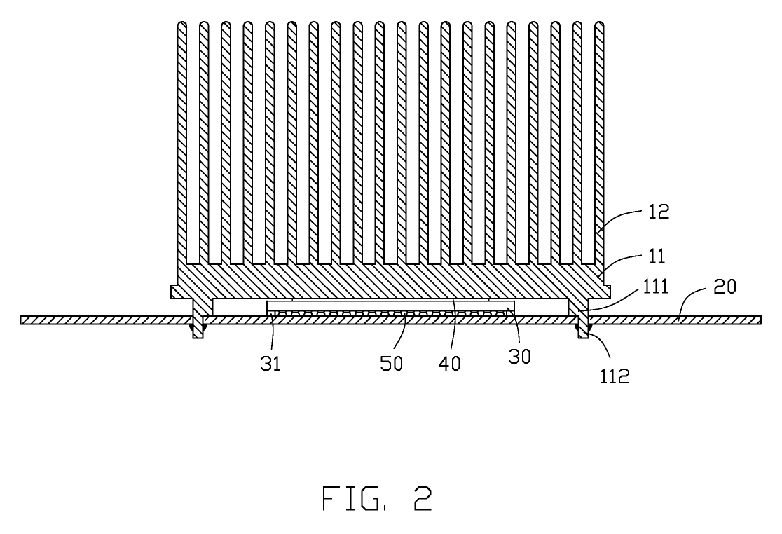

Referring to FIGS. 1 and 2, a heat sink assembly of a first embodiment comprises a PCB 20, a socket 30 attached on the PCB 20, a chip 40 received in the socket 30, and a heat sink 10 contacting a top surface of the chip 40.

The heat sink 10 comprises a base 11, a plurality of fins 12 extending up from the base 11, and four legs 110 extending down from four corners of the base 11. Each leg 110 is laddered, including a supporting portion 111 with a large cross section, and a received portion 112 with a small cross section, which extends down from the supporting portion 111. The PCB 20 defines four holes 21 corresponding to the four legs 110 of the heat sink 10. A cross section of each of the holes 21 is larger than that of the received portion 112 but smaller than that of the supporting portion 111 to stop the supporting portion 111 from passing through the holes 21. The socket 30 is attached on the PCB 20 among the four holes 21, with the four legs 31 extending down from four corners of the socket 30. An upright length of the supporting portion 112 exceeds a thickness of the socket 30. A layer of solder 50 is disposed between the socket 30 and the PCB 20. The chip 40 is received in the socket 30 being slightly taller than the socket 30. A layer of a heat-conduction medium (not labeled) is disposed on a top surface of the chip 40.

In assembly of the heat sink 10 onto the PCB 20, the received portions 112 of the heat sink 10 are received in the holes 21 of the PCB 20 respectively until the supporting portions 111 resist the top surface of the PCB 20, and the heat sink 10 compresses the layer of heat-conduction medium. Because the supporting portions 111 contact the PCB 20, pressure from the heat sink 10 is distributed between the chip 40 and the PCB 20. The chip 40 is protected from damage. The parts of the received portions 112 that pass through the holes 21 may be fastened to the bottom surface of the PCB 20, by soldering, gluing, or other means. The legs 31 contact the PCB 20, and between the solder layer 50 and the legs 31, pressure from the socket 30 and the chip 40 is further distributed. The solder layer 50 is protected from damage, and the socket 30 stably meets the PCB 20.

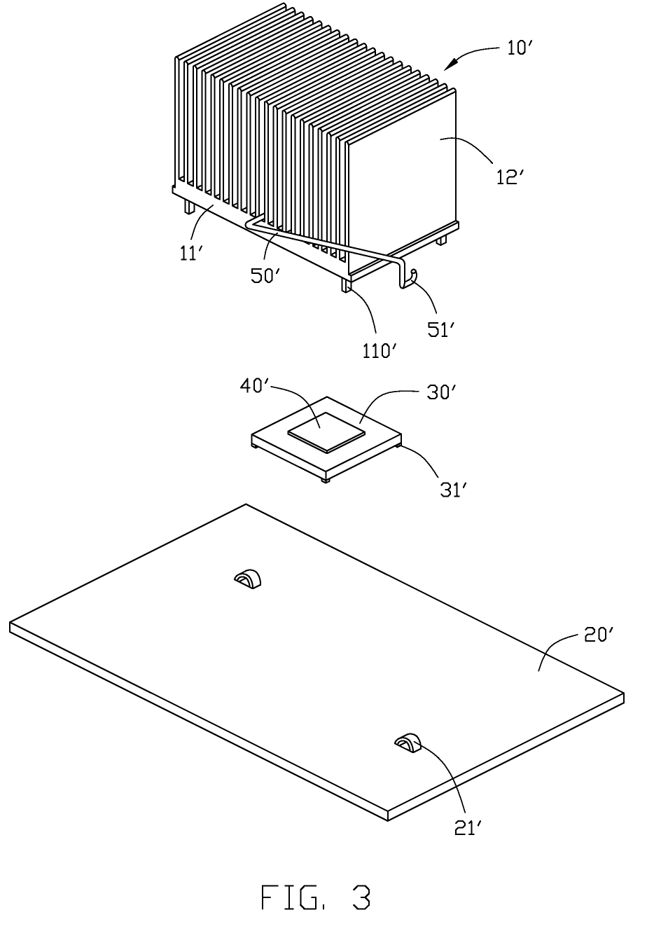

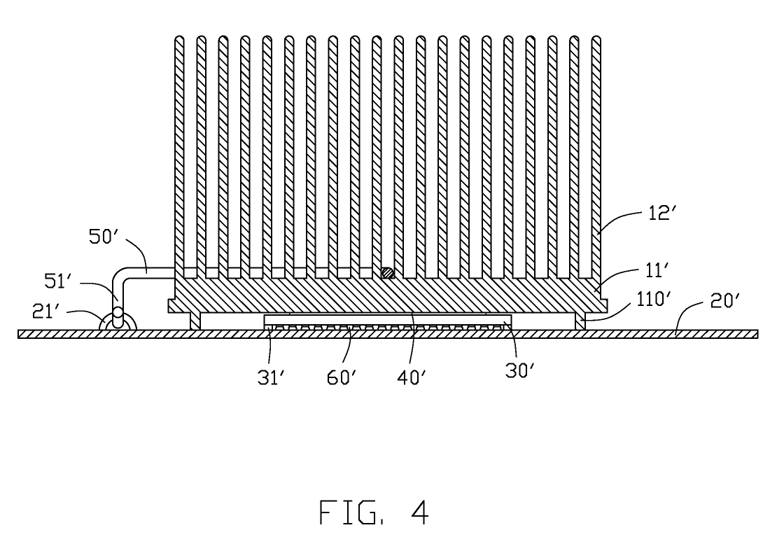

Referring to FIGS. 3 and 4, a heat sink 10′ in a second embodiment provides heat dissipation of a chip 40′ received in a socket 30′ attached on a PCB 20′. In this embodiment, a heat sink clip 50′ fastens the heat sink 10′ on the PCB 20′.

The heat sink 10′ comprises a base 11′, a plurality of fins 12′ extending up from the base 11′, and four legs 110′ extending down from the base 11′. The upright length of the leg 110′ exceeds that of the socket 30′. The socket 30′ is attached on the PCB 20′, four legs 31′ extend down from four corners of the socket 30′. A layer of solder 60′ is disposed between the socket 30′ and the PCB 20′. The chip 40′ is received in the socket 30′ and is positioned slightly higher than the socket 30′. A layer of heat-conduction medium (not labeled) is disposed on a top surface of the chip 40′. The heat sink clip 50′ defines two latching members 51′ at the end of the heat sink clip 50′. The PCB 20′ defines two latching elements 21′ corresponding to the latching members 51′.

In assembling the heat sink 10′ onto the PCB 20′, the heat sink 10′ is laid on the PCB 20′, compressing the layer of heat-conduction medium. Distal ends of the legs 110′ away from the base 11′ contact the top surface of the PCB 20′. Because the legs 110′ contact the PCB 20′, pressure from the heat sink 10′ is distributed between the chip 40′ and the PCB 20′, and chip 40′ is protected from damage. The legs 31′ contact the PCB 20′, between the solder layer 60′ and which pressure from the socket 30′ and the chip 40′ is further distributed. The solder layer 60′ is protected from damage, and the socket 30′ stably meets the PCB 20′. Heat sink clip 50′ is mounted on the base 11′ of the heat sink 10′ and the latching members 51′ clasp the latching elements 21′ of the PCB 20′. Thus, the heat sink 10′ is fastened on the PCB 20′, as shown in FIG. 4.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink assembly, comprising:
a printed circuit board;
a socket, having a chip thereon, attached on a top surface of the board, the socket comprises a plurality of legs integrally extending down from a bottom surface thereof, wherein the legs contact the top surface of the board;
a heat sink mounted on the board, the heat sink is in thermal contact with the chip, a plurality of fins extend up from a base, and a plurality of legs integrally extending down from the base.

2. The heat sink assembly of claim 1, wherein each leg has a supporting portion and a received portion, and the board defines a plurality of holes corresponding to the legs of the heat sink, the received portions are received through the holes and the supporting portions are in contact with the top surface of the board.

3. The heat sink assembly of claim 2, wherein the cross sections of the supporting portions are greater than those of the received portions.

4. The heat sink assembly of claim 1, wherein a plurality of grooves are defined on the top surface of the board for receiving the legs of the socket.

5. The heat sink assembly of claim 1, wherein a layer of heat-conduction medium is disposed between the chip and the base.

6. The heat sink assembly of claim 1, wherein the heat sink is fastened on the board by a heat sink clip; the heat sink clip biases the base against the board.

7. The heat sink assembly of claim 2, wherein the received portions are fastened to a bottom surface of the board.

8. The heat sink assembly of claim 2, wherein the received portions are fastened to a bottom surface of the board by glue.
